(19) United States
(12) Patent Application Publication
(10) Pub. No.: US 2015/0179758 A1
(43) Pub. Date: Jun. 25, 2015

(54) SEMICONDUCTOR DEVICE AND METHOD OF MANUFACTURING THE SAME

(71) Applicant: Yasuo Ata, Tokyo (JP)

(72) Inventor: Yasuo Ata, Tokyo (JP)

(73) Assignee: Mitsubishi Electric Corporation, Tokyo (JP)

(21) Appl. No.: 14/404,269

(22) PCT Filed: Jul. 20, 2012
(86) PCT No.: PCT/JP2012/068500

§ 371 Date: Nov. 26, 2014

(51) Int. Cl. H01L 29/66; H01L 29/739; H01L 27/082; H01L 21/8222; H01L 27/088

(52) U.S. Cl. CPC H01L 29/66348; H01L 21/8222; H01L 27/088; H01L 27/0823; H01L 29/7397

(57) ABSTRACT

A main cell and a sense cell are formed in a first and second region of a semiconductor substrate respectively. A base layer is formed on a drift layer in the first and second regions. A first conductivity type impurity is implanted in the base layer by using a mask having first and second openings respectively on the first and second regions in order to form first and second emitter regions on the base layer respectively in the first and second regions. First and second contact regions, first and second trench gates, and a collector layer are formed. An area of the second opening is smaller than an area of the first opening. Threshold voltage of the sense cell is higher than threshold voltage of the main cell.

### TECHNICAL FIELD

The present invention relates to a semiconductor device and a method of manufacturing the same having a main cell outputting a main current and a sense cell outputting a sense current in proportion to the main current provided on one semiconductor substrate.

### BACKGROUND ART

In a semiconductor device having a main cell and a sense cell provided on one semiconductor substrate, an imbalance in ratio between a main current and a sense current occurs due to the difference in gate internal resistance between the main cell and the sense cell. To limit this imbalance, a method of increasing the threshold voltage of the sense cell relative to that of the main cell is used (see, for example, Patent Literature 1).

### CITATION LIST

### Patent Literature

### Patent Literature 1: Japanese Patent Laid-Open No. 2011-066121

### SUMMARY OF INVENTION

### Technical Problem

Conventionally, an impurity is implanted two times only in the sense cell in order to increase the threshold voltage of the sense cell relative to that of the main cell. Therefore the number of process steps is increased and a mask is added, resulting in an increase in manufacturing cost.

The present invention has been achieved to solve the above-described problem, and an object of the present invention is to provide a semiconductor device and a method of manufacturing the same capable of limiting an imbalance in ratio between the main current and the sense current while the manufacturing cost is not increased.

### Means for Solving the Problems

A method of manufacturing a semiconductor device according to the present invention, wherein a main cell outputting a main current is formed in a first region of a semiconductor substrate and a sense cell outputting a sense current in proportion to the main current is formed in a second region of the semiconductor substrate, includes: forming a base layer of a second conductivity type on a drift layer of a first conductivity type in the first and second regions; implanting a first conductivity type impurity in the base layer by using a mask having first and second openings respectively on the first and second regions in order to form first and second emitter regions on the base layer respectively in the first and second regions; forming first and second contact regions of the second conductivity type having an impurity concentration higher than an impurity concentration in the base layer on the base layer respectively in the first and second regions; forming first and second trench gates respectively penetrating the base layer and the first and second emitter regions; and forming a collector layer of the second conductivity type on a lower surface of the drift layer in the first and second regions, wherein an area of the second opening is smaller than an area of the first opening, and threshold voltage of the sense cell is higher than threshold voltage of the main cell.

### Advantageous Effects of Invention

The present invention makes it possible to limit an imbalance in ratio between the main current and the sense current while the manufacturing cost is not increased.

### BRIEF DESCRIPTION OF THE DRAWINGS

FIG. 1 is a circuit diagram showing a semiconductor device according to a first embodiment of the present invention.

FIG. 2 is a sectional perspective view of the semiconductor device according to the first embodiment of the present invention.

FIG. 3 is a sectional perspective view showing a process of manufacturing the semiconductor device according to the first embodiment of the present invention.

FIGS. 4 to 6 are sectional perspective views showing a process of manufacturing the semiconductor device according to the second embodiment of the present invention.

FIG. 7 is a sectional perspective view of the semiconductor device according to a third embodiment of the present invention.

FIG. 8 is a sectional perspective view showing a process of manufacturing the semiconductor device according to the third embodiment of the present invention.

### DESCRIPTION OF EMBODIMENTS

A semiconductor device and a method of manufacturing the same according to the embodiments of the present invention will be described with reference to the drawings. The same components will be denoted by the same symbols, and the repeated description thereof may be omitted.

### First Embodiment

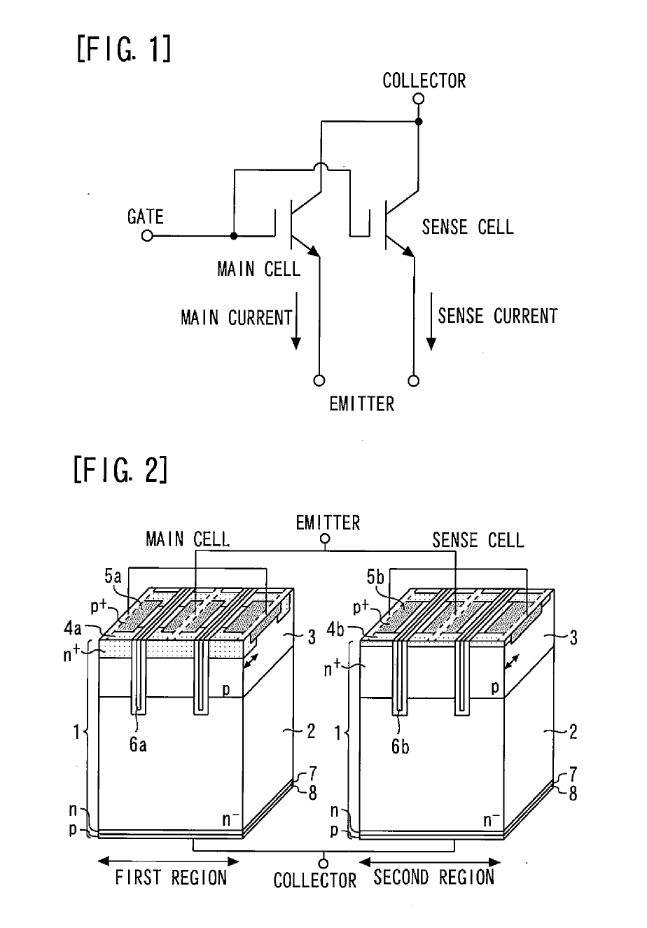

FIG. 1 is a circuit diagram showing a semiconductor device according to a first embodiment of the present invention. A main cell outputs a main current in correspondence with a gate voltage, and a sense cell outputs a sense current in proportion to the main current. The absolute value of the sense current is smaller than the absolute value of the man current, for example, about 1/1000 of the absolute value of the main current, and the waveform of the sense current corresponds generally to the waveform of the main current. It is, therefore, possible to monitor, through detection of the sense current, whether or not the value of the main current is excessively large.

FIG. 2 is a sectional perspective view of the semiconductor device according to the first embodiment of the present invention. The main cell and the sense cell are insulated gate bipolar transistors (IGBTs) respectively provided in first and second regions in one semiconductor substrate.

A p-type base layer 3 is provided on the entire area of an n⁻-type drift layer 2. In the main cell, n⁺-type emitter regions 4a and p⁺-type contact regions 5a are provided on the p-type base layer 3. In the sense cell, n⁺-type emitter regions 4b and p⁺-type contact regions 5b are provided on the p-type base layer 3. The p⁺-type contact regions 5a and 5b have an impurity concentration higher than an impurity concentration in the p-type base layer 3. A trench gate 6a is cut through the p-type base layer 3 and the n⁺-type emitter regions 4a, and a trench gate 6b is cut through the p-type base layer 3 and the n⁺-type emitter regions 4b. An n-type buffer layer 7 and a p-type collector layer 8 are successively provided on the entire area of the lower surface of each n⁻-type drift layer 2.

The n⁺-type emitter regions 4a and 4b are in the form of stripes as viewed in plan. The stripe width of the n⁺-type emitter regions 4b in the sense cell is smaller than that of the n⁺-emitter regions 4a in the main cell. Accordingly, the area of the n⁺-emitter regions 4b in the sense cell is smaller than that of the n⁺-emitter regions 4a in the main cell. Also, the depth of the n⁺-emitter regions 4b in the sense cell is larger than that of the n⁺-emitter regions 4a in the main cell. The threshold voltage of the sense cell is therefore higher than that of the main cell.

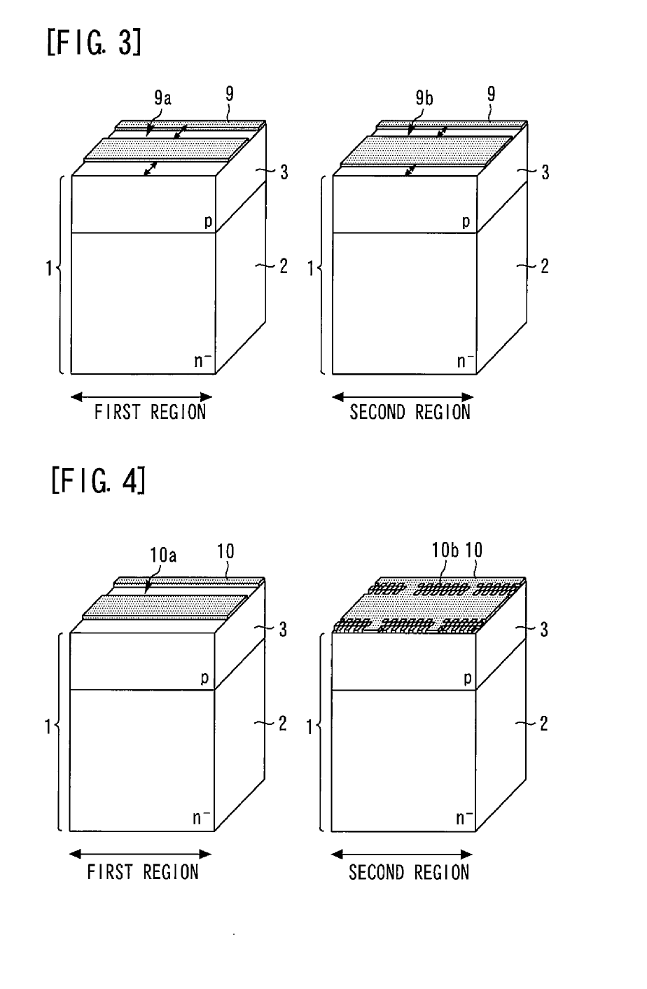

A method of manufacturing the semiconductor device according to the first embodiment will subsequently be described. FIG. 3 is a sectional perspective view showing a process of manufacturing the semiconductor device according to the first embodiment of the present invention.

First, a p-type impurity is ion implanted in the first and second regions on the n⁻-type drift layer 2 upper surface side, thereby forming the p-type base layers 3 on the n⁻-type drift layers 2. Next, as shown in FIG. 3, a mask 9 having openings 9a and 9b on the first and second regions, respectively, is formed. The openings 9a and 9b are in the form of stripes as viewed in plan. The stripe width of the openings 9b is smaller than that of the openings 9a. The area of the openings 9b is therefore smaller than that of the openings 9a. An n-type impurity is ion implanted in the p-type base layers 3 by using this mask 9. The n⁺-emitter regions 4a and 4b are thereby formed respectively on the p-type base layers 3 in the first and second regions.

Next, a p-type impurity is selectively ion implanted in the p-type base layers 3 to form the p⁺-type contact regions 5a and 5b respectively on the p-type base layers 3 in the first and second regions. Trenches to be cut through the p-type base layers 3 and the n⁺-type emitter regions 4a and 4b are then formed by etching and insulating film and conductive film are successively embedded in the trenches, thereby forming the trench gates 6a and 6b. In each of the first and second regions, the n-type buffer layer 7 and the p-type collector layer 8 are formed on the lower surface of the n⁻-type drift layer 2 by ion implantation.

Advantages of the present embodiment will be described. In the present embodiment, the stripe width of the openings 9b of the mask 9 is set smaller than the stripe width of the openings 9a of the mask 9 so that the area of the openings 9b is smaller than the area of the openings 9a. The depth of the n⁺-type emitter region 4b in the sense cell formed by using the mask 9 thus formed is larger than that of the n⁺-type emitter region 4a in the main cell. Therefore, an imbalance in ratio between the main current and the sense current can be limited by increasing the threshold voltage of the sense cell relative to that of the main cell.

Since the n⁺-type emitter regions 4a and 4b in the main and sense cells can be simultaneously formed with the same mask, there is no need to increase the number of process steps and use an additional mask, so that the manufacturing cost is not increased.

### Second Embodiment

A method of manufacturing a semiconductor device according to a second embodiment of the present invention will be described. FIGS. 4 to 6 are sectional perspective views showing a process of manufacturing the semiconductor device according to the second embodiment of the present invention.

First, the p-type base layers 3 are formed on the n⁻-type drift layers 2 in the same way as in the first embodiment. Next, as shown in FIG. 4, a mask 10 having openings 10a and 10b on the first and second regions, respectively, is formed. The openings 10a are in stripe form, as the corresponding openings in the first embodiment. The openings 10b are in the form of a plurality of dots. The area of the openings 10b is therefore smaller than that of the openings 10a.

Next, as shown in FIG. 5, an n-type impurity is ion implanted in the p-type base layers 3 by using the mask 10. The n⁺-emitter regions 4a and 4b are thereby formed respectively on the p-type base layers 3 in the first and second regions. At this point in time, the n⁺-type emitter region 4b is in the form of a plurality of dots. The mask 10 is thereafter removed.

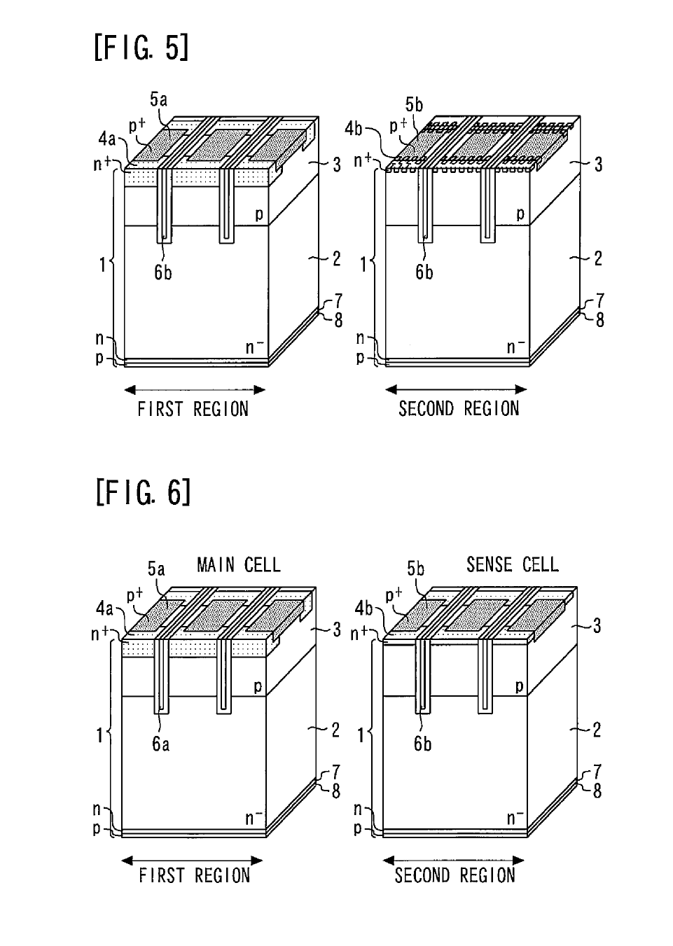

Next, the p⁺-type contact regions 5a and 5b, the trench gates 6a and 6b, the n-type buffer layer 7 and the p-type collector layer 8 are formed in the same way as in the first embodiment. Thereafter, impurity diffusion is caused by performing a heat treatment. The state of the n⁺-type emitter regions 4a and 4b after this treatment is such that the impurity is continuously diffused, as shown in FIG. 6.

The n⁺-emitter regions 4b of the sense cell are formed by using the mask 10 having the openings 10b in the form of a plurality of dots as described above, thereby enabling setting the depth of the n⁺-type emitter regions 4b in the sense cell smaller than that of the n⁺-type emitter regions 4a in the main cell while setting the width of the n⁺-type emitter regions 4b in the sense cell equal to that of the n⁺-type emitter regions 4a in the main cell. Other advantages, which are the same as those of the first embodiment, can also be obtained.

### Third Embodiment

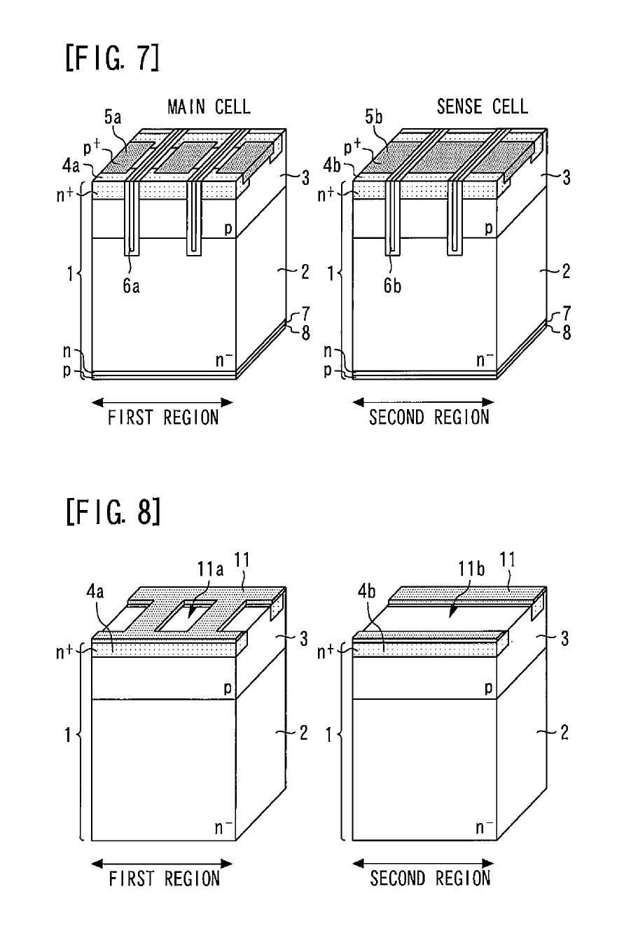

FIG. 7 is a sectional perspective view of the semiconductor device according to a third embodiment of the present invention. The n⁺-type emitter regions 4a in the main cell and the n⁺-type emitter regions 4b in the sense cell are equal to each other in depth and other factors unlike those in the first embodiment. However, the area of the p⁺-type contact regions 5b in the sense cell is larger than that of the p⁺-contact regions 5a in the main cell, and the depth of the p⁺-type contact regions 5b in the sense cell is larger than that of the p⁺-type contact regions 5a in the main cell. The threshold voltage of the sense cell is therefore higher than that of the main cell.

A method of manufacturing the semiconductor device according to the third embodiment of the present invention will be described. FIG. 8 is a sectional perspective view showing a process of manufacturing the semiconductor device according to the third embodiment of the present invention.

First, the p-type base layers 3 are formed on the n⁻-type drift layers 2 in the same way as in the first embodiment, and the n⁺-type emitter regions 4a and 4b equal to each other in depth and other factors are formed on the p-type base layers 3. Next, as shown in FIG. 8, a mask 11 having openings 11a and 11b on the first and second regions, respectively, is formed. The area of the opening 11b is larger than that of the opening 11a. A p-type impurity is ion implanted in the p-type base layers 3 by using this mask 11, thereby forming the p⁺-type contact regions 5a and 5b respectively on the p-type base layers 3 in the first and second regions. The trench gates 6a and 6b, the n-type buffer layers 7 and the p-type collector layers 8 are thereafter formed in the same way as in the first embodiment.

Advantages of the present embodiment will be described. In the present embodiment, the opening 11b is made larger in area than the opening 11a. The area of the p⁺-type contact regions 5b in the sense cell is thereby made larger than that of the p⁺-type contact regions 5a in the main cell. The p-type impurity concentration in the vicinity of the trench gate 6b is therefore higher than that in the vicinity of the trench gate 6a. The threshold voltage of the sense cell can thus be made higher than that of the main cell to limit an imbalance in ratio between the main current and the sense current.

Also, the p⁺-type contact regions 5a and 5b of the main and sense cells can be simultaneously formed with one mask. An increase in the number of process steps and addition of a mask can therefore be avoided. In this case, therefore, the manufacturing cost is not increased.

In the above-described first to third embodiments, it is preferable that the ratio of the areas of the n⁺-type emitter regions 4a and the p⁺-type contact regions 5a in the main cell be made equal to the ratio of the areas of the n⁺-type emitter regions 4b and the p⁺-type contact regions 5b in the sense cell. The threshold voltage of the sense cell can thereby be made higher than that of the main cell without changing main characteristics other than the threshold voltage.

The semiconductor forming each of the semiconductor devices according to the above-described embodiments is not limited to silicon. The semiconductor device may be formed of a wide-band-gap semiconductor having a band gap larger than that of silicon. The wide-band-gap semiconductor is, for example, silicon carbide, a gallium nitride-based material or diamond. A semiconductor device formed of such a wide-band-gap semiconductor has a high withstand voltage and a high allowable current density and can therefore be reduced in size. A semiconductor module incorporating the semiconductor device reduced in size can also be reduced in size. Also, radiating fins of a heat sink for the semiconductor module can be made smaller in size and a water-cooling part can be replaced with an air-cooling part, because the semiconductor device has high heat resistance. Also, the device has a low power loss and high efficiency and the efficiency of the semiconductor module can therefore be improved.

### DESCRIPTION OF SYMBOLS

2 n⁻-type drift layer
3 p-type base layer
4a n⁺-type emitter region (first emitter region)
4b n⁺-type emitter region (second emitter region)
5a p⁺-type contact region (first contact region)
5b p⁺-type contact region (second contact region)
6a trench gate (first trench gate)
6b trench gate (second trench gate)
8 p-type collector layer
9,10,11 mask
9a,10a,11a opening(first opening)
9b,10b,11b opening(second opening)

1-9. (canceled)

10. A method of manufacturing a semiconductor device, wherein a main cell outputting a main current is formed in a first region of a semiconductor substrate and a sense cell outputting a sense current in proportion to the main current is formed in a second region of the semiconductor substrate, comprising:
forming a base layer of a second conductivity type on a drift layer of a first conductivity type in the first and second regions;
implanting a first conductivity type impurity in the base layer by using a mask having first and second openings respectively on the first and second regions in order to form first and second emitter regions on the base layer respectively in the first and second regions;
forming first and second contact regions of the second conductivity type having an impurity concentration higher than an impurity concentration in the base layer on the base layer respectively in the first and second regions;
forming first and second trench gates respectively penetrating the base layer and the first and second emitter regions; and
forming a collector layer of the second conductivity type on a lower surface of the drift layer in the first and second regions,
wherein an area of the second opening is smaller than an area of the first opening, and
threshold voltage of the sense cell is higher than threshold voltage of the main cell.

11. The method of manufacturing the semiconductor device according to claim 10, wherein the first and second openings are in a form of stripes as viewed in plan, and
a stripe width of the second opening is smaller than a stripe width of the first opening.

12. The method of manufacturing the semiconductor device according to claim 10, wherein the second opening is in a form of a plurality of dots.

13. The method of manufacturing the semiconductor device according to claim 10, wherein a ratio of areas of the first emitter region and the first contact region is equal to a ratio of areas of the second emitter region and the second contact region.

14. A method of manufacturing a semiconductor device, wherein a main cell outputting a main current is formed in a first region of a semiconductor substrate and a sense cell outputting a sense current in proportion to the main current is formed in a second region of the semiconductor substrate, comprising:
forming a base layer of a second conductivity type on a drift layer of a first conductivity type in the first and second regions;
implanting a first conductivity type impurity in the base layer by using a mask having first and second openings respectively on the first and second regions in order to form first and second emitter regions on the base layer respectively in the first and second regions;
forming first and second contact regions of the second conductivity type having an impurity concentration higher than an impurity concentration in the base layer on the base layer respectively in the first and second regions;
forming first and second trench gates respectively penetrating the base layer and the first and second emitter regions; and
forming a collector layer of the second conductivity type on a lower surface of the drift layer in the first and second regions,
wherein an area of the second contact region is larger than an area of the first contact region, and
threshold voltage of the sense cell is higher than threshold voltage of the main cell.

15. The method of manufacturing the semiconductor device according to claim 14, wherein a ratio of areas of the first emitter region and the first contact region is equal to a ratio of areas of the second emitter region and the second contact region.

16. A semiconductor device comprising:
a semiconductor substrate;
a main cell outputting a main current and provided in the semiconductor substrate; and
a sense cell outputting a sense current in proportion to the main current and provided in the semiconductor substrate,
wherein each of the main cell and the sense cell includes:
a drift layer of a first conductivity type;
a base layer of a second conductivity type on the drift layer;
an emitter region of the first conductivity type on the base layer;
a contact region of the second conductivity type on the base layer and having an impurity concentration higher than an impurity concentration in the base layer;
a trench gate penetrating the base layer and the emitter region; and
a collector layer of the second conductivity type on a lower surface of the drift layer,
an area of the emitter region in the sense cell is smaller than an area of the emitter region in the main cell, and
threshold voltage of the sense cell is higher than threshold voltage of the main cell.

17. The semiconductor device according to claim 16, wherein the emitter region is in a form of a stripe as viewed in plan, and
a stripe width of the emitter region in the sense cell is smaller than a stripe width of the emitter region in the main cell.

18. The semiconductor device according to claim 16, wherein a ratio of areas of the emitter region and the contact region in the main cell is equal to a ratio of areas of the emitter region and the contact region in the sense cell.

19. A semiconductor device comprising:
a semiconductor substrate;
a main cell outputting a main current and provided in the semiconductor substrate; and
a sense cell outputting a sense current in proportion to the main current and provided in the semiconductor substrate,
wherein each of the main cell and the sense cell includes:
a drift layer of a first conductivity type;
a base layer of a second conductivity type on the drift layer;
an emitter region of the first conductivity type on the base layer;
a contact region of the second conductivity type on the base layer and having an impurity concentration higher than an impurity concentration in the base layer;
a trench gate penetrating the base layer and the emitter region; and
a collector layer of the second conductivity type on a lower surface of the drift layer,
an area of the contact region in the sense cell is larger than an area of the contact region in the main cell, and
threshold voltage of the sense cell is higher than threshold voltage that of the main cell.

20. The semiconductor device according to claim 19, wherein a ratio of areas of the emitter region and the contact region in the main cell is equal to a ratio of areas of the emitter region and the contact region in the sense cell.
